(19) United States
(12) Patent Application Publication
(10) Pub. No.: US 2002/0067645 A1
(43) Pub. Date: Jun. 6, 2002

(54) Method and system for increasing timing margins without deteriorating a data transfer rate

(75) Inventors: Tadashi Ohmori, Shiga-ken (JP); Hiroshi Oshikawa, Kanagawa-ken (JP); Masahiro Shimizu, Kanagawa-ken (JP); Kohji Yamada, Shiga-ken (JP)

Correspondence Address: BRACEWELL & PATTERSON, L.L.P., 7600B NORTH CAPITAL OF TEXAS HIGHWAY, SUITE 350, AUSTIN, TX, 78731-1168, US

(73) Assignee: International Business Machines Corp., Armonk, NY

(21) Appl. No.: 10/010,611

(22) Filed: Dec. 3, 2001

(30) Foreign Application Priority Data
Dec. 5, 2000 (JP) 2000-370626

(51) Int. Cl. G11C 29/00

(52) U.S. Cl. 365/200

(57) ABSTRACT

A slew rate of a data signal is controlled to be smaller than a slew rate of a strobe signal by independently controlling the slew rate of the data signal and slew rates of control signals by controlling the strobe signal with the slew rate controller of the driver. The gradient of the signal waveform is controlled in the transition times of the strobe signal to be greater than that of the data signal.

### BACKGROUND OF THE INVENTION

1. Technical Field

This invention relates to a data transfer system, a data transfer method, a storage device, a computer system, and specially to an art that is effective when applied to quality improvement for data transfer conforming to the AT Attachment (ATA)/ATA Packet Interface (ATAPI) Specifications.

2. Description of the Related Art

A personal computer system conforming to the AT Specifications usually uses a hard disk drive (HDD) as a storage device. A flat cable is used to connect the main board and HDD of the computer system via an interface. An integrated drive electronics (IDE) (called Enhanced IDE in ATA-2 and later editions) is the adopted standard as an interface for data transfer.

The IDE is standardized as ATA-1, then gradually extended to ATA-2 and ATA-3. The current standardization to ATA/ATAPI-5 is the newest standard. In near future, ATA/ATAPI-6 will be established. ATA established later is high-order compatible and so conformance to ATA/ATAPI-5 means conformance to ATA-1 to ATA-4 at the same time. In addition, ATAPI is the specification that makes storage devices such as a compact disk ROM (CD-ROM), a digital video disk ROM (DVD-ROM), -and a magnetooptical disk (MO) connected to conventional systems with a small computer system interface (SCSI) also usable with the IDE. ATAPI is integrated with ATA in ATA/ATAPI-4 and later editions. The IDE interface has three types of transfer systems; a programmed I/O (PIO), a multi-word direct memory access (DMA), and an UltraDMA. The IDE also has multiple modes with different maximum transfer rates. The PIO is a method for a processor to control data read and write in mode 0 (maximum transfer rate of 3.33 MB/s) to mode 4 (maximum transfer rate of 16.7 MB/s). The multi-word DMA is a method for a DMA controller to control data transfer in modes 0 to 2. The maximum transfer rate in mode 0 is 4.17 MB/s and the maximum transfer rate in mode 2 is 16.7 MB/s. The UltraDMA enables the twice as high transfer rate as that at the same clock frequency of the multi-word DMA by reading and writing data at both rise and fall of a clock. There are mode 0 (maximum transfer rate of 16.7 MB/s) to mode 4 (maximum transfer rate of 66.6 MB/s), and mode 5 (maximum transfer rate of 100 MB/s) is being established as ATA/ATAPI-6. For example, in the case of conformance to the ATA/ATAPI-6 Specifications, the range of 3.33 MB/s to 100 MB/s need be coped with as the maximum transfer rate.

When the IDE applies, up to two HDDs or CD-ROMs can be connected to one IDE port and the IDE cable is therefore configured so that one host side connector corresponds to two device side connectors by branching the IDE cable at its halfway or end. For the cable of UltraDMA/66 (maximum transfer rate of 66.6 MB/s) or later, grounding cables are doubled, that is, the signal line is isolated by grounding cables to inhibit an influence of an increasing noise.

Conventionally, parallel data transfer specifications such as the IDE or SCSI have multiple data signal lines. For example, the IDE has 16 data signal lines. Accordingly, the number of bits corresponding to the number of data signal lines (16 bits for the IDE) are transferred at the same time in one cycle. To control a data read timing of a data signal line, one strobe signal of a control signal line is used. The signal level of the data signal line is read at rise time or fall time of a strobe signal, and information of “1” or “0” corresponding to a high level or low level is transferred.

To secure information transfer, the data signal needs to be stable before and after a read timing of the strobe signal. FIG. 9 shows an example of the data signal and strobe signal timing. The stabilization time before the read timing is called setup time and that after the read timing is called hold time. Sufficiently securing the both times is a condition of stable data transfer. FIG. 9 shows an example of data reading at the fall time of the strobe signal, but when the UltraDMA method applies, data is also read at the rise time.

However, as aforementioned, data transfer specifications such as the ATA aim to improve the transfer rate. In other words, a clock frequency (number of cycles of each signal) tends to increase. Conventionally, a signal is not a complete rectangle wave, but has specific rise and fall times. These times are called transition times in this description. When the clock frequency increases, the transition times need be decreased to secure sufficient setup and hold times. Thus, the transition times need to be decreased according to the increase of the clock frequency.

On the other hand, decrease of the transition times increases a cross-talk noise between data signal lines. When the transition times are short, that is, a waveform close to a rectangle wave is enabled, a signal contains many high-frequency elements. Wires allocated in parallel are connected with a parasitic capacitance, and at higher frequencies, adjacent wires are coupled easily. As a result of the coupling, a data signal is affected by an adjacent data signal. For the cables conforming to UltraDMA/66 and later versions, the data signal line is surrounded by grounding lines to reduce a cross-talk noise, but measures for a cross-talk noise are not taken for cables conforming to earlier versions. Thus, an essentially high-level signal may be judged to be a low-level signal and low-level signal may be judged as a high-level signal due to an influence of the cross-talk noise. Accordingly, from the viewpoint of reliability of data transfer, the cross-talk noise needs to be inhibited as much as possible and the transition times need to be as large as possible. In other words, increasing the transition times within the range corresponding to the data transfer rate seems to be the most effective measure to secure the reliability of data transfer while maintaining a high data transfer rate.

However, there is a problem that increase of the transition times decrease the timing margin when a data sending side sends a clock (strobe) signal with a data signal to a receiving side such as data transfer of the UltraDMA method.

Conventionally, a data signal level is judged to be high or low byjudging whether it is higher or lower than threshold voltage Vt. However, the real threshold value varies to because of unevenness of semiconductor elements in a manufacturing process, an ambient temperature, or a power supply voltage. Accordingly, two types of threshold values are defined for the receiver as specifications. If the data signal level is higher than first threshold voltage Vth, it is always judged to be high. If the data signal level is lower than the second threshold voltage Vtl, it is always judged to be low. To eliminate difference in judgment caused by unevenness, Vth is set higher than Vtl. The real threshold value Vt of a receiver is in-between Vth and Vtl. Vt depends on each receiver. Vt may be close to Vth or Vtl.

FIG. 10 shows timings of the data signal and strobe signal under such conditions. FIG. 10 is a drawing typically showing the timing to explain this issue. (a) shows the case in which Vt is close to Vth. (b) shows the case in which Vt is close to Vtl. Although the data signal and strobe signal are received at the same timing in (a) and (b), the hold time greatly deteriorates in the case of (b). A change in the read timing of the data signal due to a change in the receiver threshold value causes such deterioration of the hold time. That is, even though signals are input at the same time, the timing margins may be deteriorated by a change in the threshold value of the receiver. Such deterioration of the timing margins becomes remarkable when the transition time of the strobe signal is long. FIG. 10 shows an example of data read at a fall time of the strobe signal, but when data is read at a rise time of the strobe signal, a setup time deteriorates. In either case, the timing margins also deteriorate.

In addition to the problem of increasing the transition times, there is a problem of deterioration of a signal waveform caused by a difference in specifications of each signal line for the strobe signal or the data signal. When UltraDMA applies, the “IORDY” line is used for data strobe at data read. This “IORDY” is pulled up by the resistance of 1 k ohm in the host system side, and the dumping resistance of the HDD in the device side is usually 22 ohm. On the other hand, the line for transferring the data signal is not pulled up, and the dumping resistance of the device side is usually 33 ohm. Thus, electric features of the strobe line and data line, for example, a load impedance from the driver's view differs, and its waveform differs when a signal is applied from the same driver. Even if an effort is made to arrange dumping resistance and line lengths in the device side to arrange data skews, pulling up in the host system side cannot be changed. Accordingly, even if the slew rate control of the driver is used, slew rates, overshoots, or undershoots of the strobe signal and data signal cannot be arranged. If the driver is adjusted so that the strobe signal waveform becomes optimum, the data signal is not optimum, and if the data signal is adjusted to optimum, the strobe signal is not optimum. Such shift from the optimum waveform of the signal generates a reflection by a transmitted signal, and moreover, causes disfigurement of the waveform. Especially, more careful design is needed and a flexible adjustment engineering is strongly required in the specifications of the next generation such as UltraDMA/100. Such a difference in a load impedance between signal lines also occurs in the following case: When the ATA/ATPI applies, up to two devices can be attached to the cable connected to one host side IDE port, but a load impedance of a signal line from the driver's view differs depending on whether one device is or two devices are attached. Accordingly, if the driver is adjusted so that a signal waveform becomes optimum when one device is attached, the signal waveform shifts from the optimum waveform when two devices are attached. If the driver is adjusted so that the signal waveform becomes optimum when two devices are connected, it is not optimum when one device is attached.

An object of the invention is to provide an engineering of improving data transfer reliability by increasing the timing margins without deteriorating the data transfer rate. Another object of the invention is to provide a flexible adjustment engineering for a signal waveform enabling arranging skews of the data signal and strobe signal. A further object of the invention is to provide an engineering to secure the reliability of data transfer regardless of the number of devices attached to cables.

### SUMMARY OF THE INVENTION

The outline of the claimed invention is as follows: The invention uses a slew rate controller to independently control the slew rate of the data signal and the slew rate of the strobe signal and make the slew rate of the data signal smaller than the slew rate of the strobe signal. With regard to a signal waveform, gradient of a waveform in the transition times of the strobe signal is made greater than that of the data signal. Thus, by independently controlling the slew rates of the data signal and strobe signal, the slew rate of the data signal can be adjusted to small so that cross-talk can be minimized within the range of maintaining the transfer rate. By making the slew rate of the strobe signal greater than that of the data signal, deterioration of the timing margin can be inhibited. Because data signal lines are allocated in parallel, a cross-talk between these lines appears from switching, and so a solution for correcting cross-talk is presented. On the other hand, for the strobe signal, because cross-talk is not remarkable in comparison with the data signal line, a solution for improving the timing margin is presented. By reducing the transition time of the strobe signal, even if unevenness of the threshold value occurs due to unevenness of elements, a temperature, or a driving voltage, the data read timing variance caused by threshold value variance is small and deterioration of the setup time or hold time margin can be made small. Preferably, a difference between a time for the data signal to transit between a first reference data voltage and a second reference data voltage (Vth and Vtl) and a time for the strobe signal to transit between a first reference control voltage and a second reference control voltage (Vth and Vtl) is 2 ns or more. Vth and Vtl are logical high and low voltages, respectively. Vth for the first reference data voltage and the first reference control voltage may be the same voltage level or different voltage levels, just as Vtl may be the same or different voltage levels.

Waveforms of the strobe signal and data signal also differ depending on the number of devices connected to the IDE ports (cables). Accordingly, objects of the invention are to judge whether a second device is connected to a cable, read an optimum slew rate set when the second device is connected and not connected from the table in which these slew rates are recorded beforehand, and enable generating a signal by applying the optimum slew rate according to the number of connected devices. Another object of the invention is to enable independently controlling slew rates at rise and fall times of the signal waveform. By aforementioned measures, the reliability of data transfer can be improved by controlling the signal waveform to optimum.

The invention can be grasped as the data transfer method, the storage device such as an HDD in which these data transfer method and system are implemented, and the computer system in addition to the data transfer system.

### BRIEF DESCRIPTION OF THE DRAWINGS

The novel features believed characteristic of the invention are set forth in the appended claims. The invention itself, however, as well as a preferred mode of use, further objects and advantages thereof, will best be understood by reference to the following detailed description of an illustrative embodiment when read in conjunction with the accompanying drawings, wherein:

FIG. 1 shows a block diagram showing an example of a computer system, which is one embodiment of the present invention;

FIG. 2 shows a DRU of a host system and a DRU and cable of a hard disk drive;

FIG. 3 shows a circuit diagram showing concrete examples of a driver and a receiver;

FIG. 4 shows a flowchart showing an example of a data transfer method, which is one embodiment of the present invention;

FIG. 5 shows an example of setting a slew rate of a strobe signal large and a slew rate of a data signal small;

FIG. 6(a) shows a graph of observing a strobe signal of the receiver side by using the driver, which is one embodiment of the present invention;

FIG. 6(b) shows a graph showing a data signal at the receiver side to which a low-level is input under the condition of full-swinging adjacent data signal lines;

FIGS. 7(a) and (b) show a graph of the conventional strobe signal (a) and data signal (b) depicted for comparison;

FIG. 8 shows a graph of a data signal at the receiver side in the case of changing a slew rate;

FIG. 8(a) shows the case in which a slew rate is small;

FIG. 8(b) shows the case in which a slew rate is large;

FIG. 9 depicts examples of a data signal and strobe signal; and

FIG. 10 shows a drawing typically showing timings to explain an object of the present invention.

### DETAILED DESCRIPTION OF THE PREFERRED EMBODIMENT

Embodiments of the present invention will be herein explained using accompanied drawings. However, the present invention can be applied in many different modes and so interpretation should not be limited to the contents of the embodiments of the present invention. The same numbers are assigned to the same elements throughout the description.

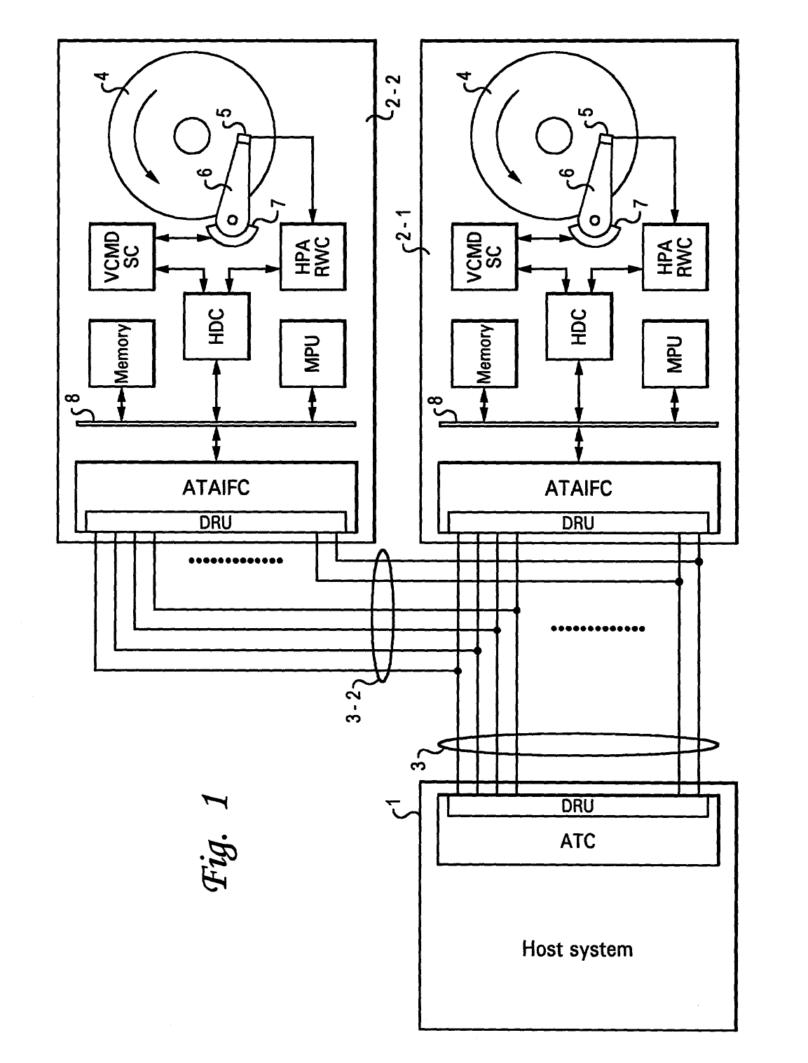

FIG. 1 shows a block diagram showing an example of a computer system; a mode for carrying out the invention. The computer system of this mode for carrying out the invention comprises host system 1 and two hard disk drives (HDD) 2-1 and 2-2. Host system 1 and HDD 2-1 are interconnected with cable 3. Host system 1 and HDD 2-2 are interconnected with cable 3-2 branched from cable 3.

Host system 1 is a computer system consisting of a bus architecture of a processor bus, a peripheral component interface (PCI) bus, and an industrial standard architecture (ISA) bus. A CPU, a main memory, a direct memory access (DMA) controller, a memory/bus control chip set, an I/O interface, a display interface, an external interface and so forth are connected to the buses. Host system 1 also can have arbitrary hardware resources with which any usual computer system is equipped.

Host system 1 has AT controller ATC to interface with HDDs 2-1 and 2-2. The ATC is an interface that conforms to ATA-1 to ATA/ATAPI-5, and will also conform to specifications established in the future (e.g., ATA/ATAPI-6). The ATC includes a driver/receiver unit (DRU) connected to each wire of cable 3.

Each of hard disk drive 2-1 and 2-2 has a medium 4 for storage such as a disk, magnetic head 5, arm 6, voice coil motor (VDM) 7, head preamplifier (HPA), read/write channel (RWC), VCM driver (VCMD), servo controller (SC), hard disk controller (HDC), a memory, an Microprocessor Unit (MPU), and ATA interface circuit (ATAIFC).

The medium 4 is rotated by, for example, a spindle motor, and information is recorded on it by using a magnetic action. The information stored on the medium 4 is read by magnetic head 5. Information is also written from magnetic head 5. Magnetic head 5 is allocated on the end of arm 6. Arm 6 is driven by VCM7 to change a relative location on storage medium 4. VCM7 is driven by VCM driver VCMD and controls head 5 to a target position according to feedback from a servo controller (SC).

A signal read from head 5 is amplified by head preamplifier HPA and sent to read/write channel RWC. Read/write channel RWC converts the electric signal into data and sends the data to the hard disk controller. Read/write channel RWC furthermore converts the data sent from hard disk controller HDC into an electric signal and sent it to magnetic head 5.

VCM driver VCMD and read/write channel RWC are connected to hard disc controller HDC, and hard disk controller HDC controls the connected devices.

Hard disk controller HDC, the memory, and the MPU are connected to bus 8 and exchange data via bus 8. The memory stores data specific to the hard disk drive (e.g., table) such as a program controlling hard disk drive 2. The memory also buffers data sent from the host system. The MPU controls the entire hard disk drive according to the control program.

ATA interface circuit ATAIFC is connected to bus 8. ATAIFC interfaces communication with host system 1. ATAIFC is an interface that conforms to ATA-1 to ATA/ATAPI-5 and will conform to specifications established in the future (e.g., ATA/ATAPI-6). ATAIFC comprises driver/receiver unit DRU connected to each wire of cable 3.

Cable 3 connecting the ATC and the DRU of hard disk drive 2-1 is a flat cable consisting of forty (40) or eighty (80) wires. Cable 3 comprises 16 data lines in addition to grounding lines, control signal lines. If cable 3 consists of 80 wires, grounding lines are allocated between the wires as a measure for a cross-talk noise. Cable 3 is branched to cable 3-2 in halfway. Cable 3-2 is connected to the DRU of hard disk drive 2-2.

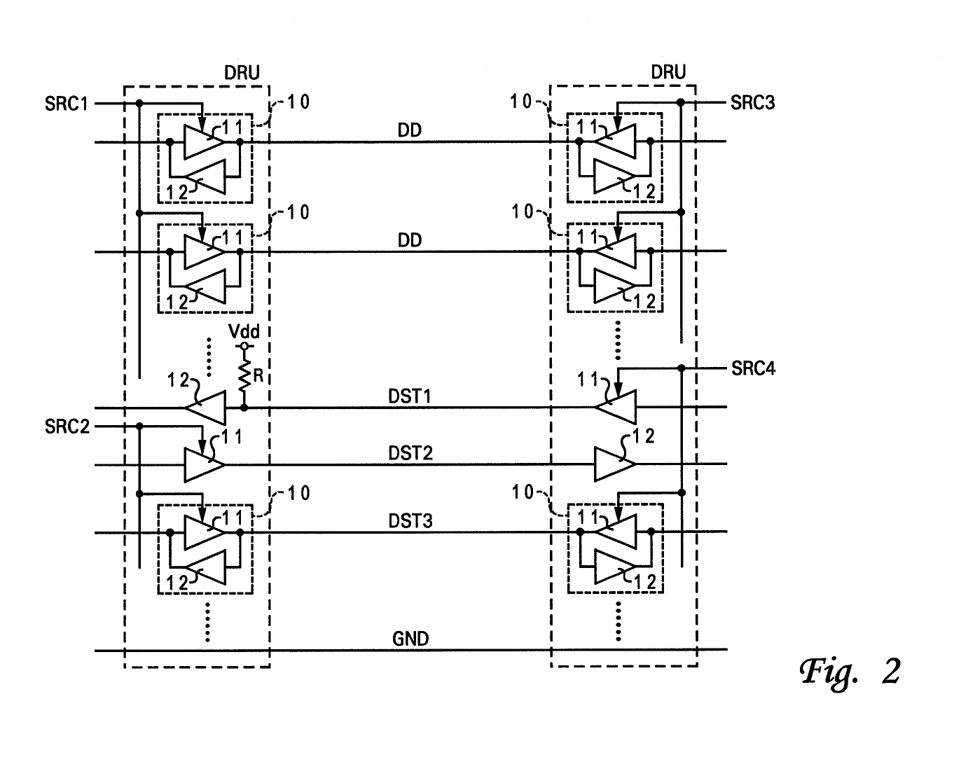

FIG. 2 shows the DRU of host system 1 and the DRU and cable of hard disk drive 2-1 or 2-2. Each DRU includes driver/receiver circuit 10. Driver/receiver circuit 10 consists of driver 11 and receiver 12. DRUs are connected by data signal line DD, control signal line DST1, DST2, DST3, and grounding line GND.

Data signal line DD transmits a data signal in both ways between the host system and the HDD. Driver/receiver circuits 10 are connected to both ends of data signal line DD. When transferring data from the host to the HDD, driver/receiver circuit 10 of the host side functions as driver 11 and driver/receiver circuit 10 of the HDD side functions as receiver 12. When transferring data from the HDD to the host, driver/receiver circuit 10 of the host side functions as receiver 12 and driver/receiver circuit 10 of the HDD side functions as driver 11. There are 16 (sixteen) data signal lines DD, but they are omitted in the figure.

Control signal line DST1 (called “IORDY”) is a one-way transmission line used to transmit a strobe signal from the HDD side to the host side at transfer in the UltraDMA method. Receiver 12 is connected to the host side of control signal line DST1 and driver 11 is connected to the HDD side. The strobe signal transmitted to control signal line DST1 is used to take a read timing of the data signal transmitted by the UltraDMA method from the HDD side. Control signal line DST1 is pulled up by 1 k ohm resister R at the host side.

Control signal line DST2 (called “DIOW-”) is a one-way transmission line used to transmit a write strobe signal sent from the HDD side to the host side at transfer in the PIO method or multi word DMA method. Control signal line DST3 (called “DIOR-”) is a one-way transmission line used to transmit a write strobe signal from the host side to the HDD side at transfer of the PIO method or multi word DMA method and to transmit a write strobe signal from the host side to the HDD side at data transfer in the UltraDMA method. Explanation of other control signal lines are omitted.

A slew rate control signal SRC1 is input to driver 11 of the host connected to data signal line DD. A slew rate control signal SRC2 is input to driver 11 of the host connected to control signal lines DST2 and DST3. A slew rate control signal SRC3 is input to driver 11 of the HDD connected to data signal line DD. A slew rate control signal SRC4 is input to driver 11 of the HDD connected to control signal line DST1. Thus, in the mode of carrying out the invention, the DRU can separately control the slew rate of the data driver generating a data signal and the slew rate of the control driver generating a control signal. Accordingly, the reliability of data transfer can be improved without deteriorating the transfer rate as explained later.

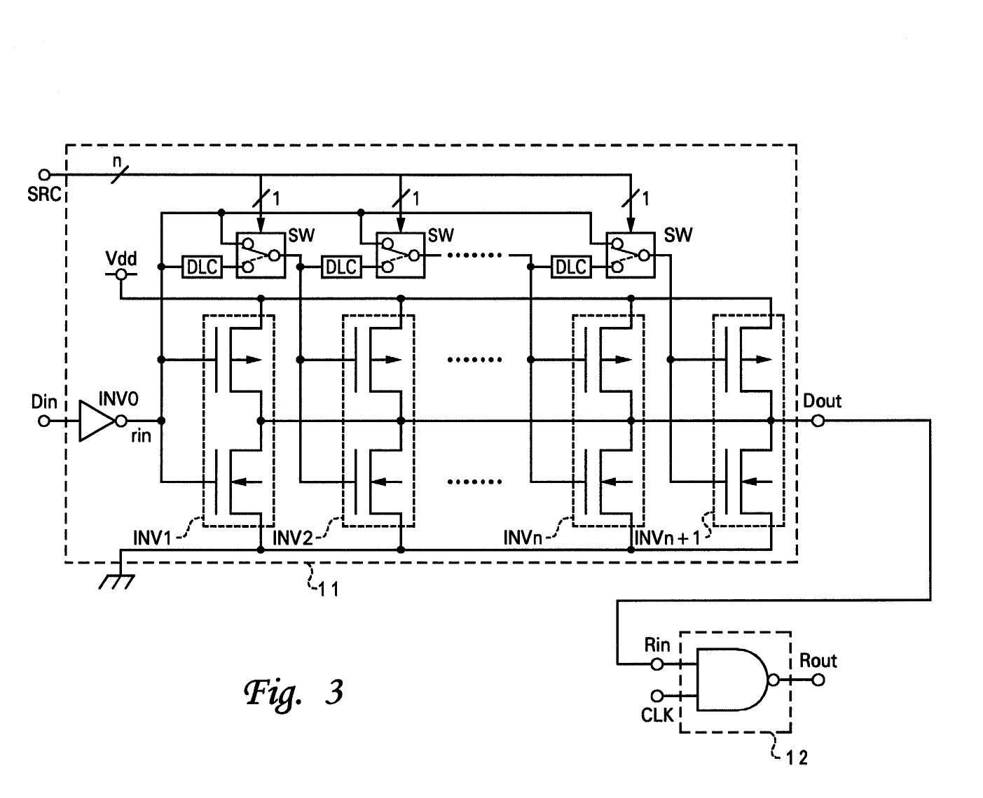

FIG. 3 is a circuit diagram showing a concrete example of driver 11 and receiver 12. In the mode of carrying out the invention, driver 11 consists of inverters of two stages; inverter INVO of the initial stage and the inverter of the rear stage.

The inverter of the rear stage has the configuration wherein multiple inverters connected in parallel enables selection of direct input or input via delay circuit DLC of rear stage inverter input rln with switch SW. However, the input of first inverter INV1 of the rear stage inverter is only rear stage inverter input rIn. Switch SW selects input via delay circuit DLC or direct input of rln according to each bit of slew rate control signal SRC.

For example, when each bit of slew rate control signal SRC is set so that all switches SW select rIn input side, initial stage inverter INVO output rIn is input to all inputs of rear stage inverters INV1 to INVn+1 at the same time. In other words, all rear stage inverters INVI to INVn+1 are driven at almost simultaneously with input Din to the driver and driver 11 is driven at the maximum allowable current. In this case, output from driver 11 Dout performs the fastest step response and enables the maximum slew rate.

When each bit of slew rate control signal SRC is set so that all switches SW select the delay circuit (DLC) side, rear stage inverter INV2 is driven after delay time T from driving rear stage inverter INV1. After time T from driving rear stage inverter INV2 (that is, 2T from driving INV1), rear stage inverter INv3 is driven. Rear stage inverters are sequentially driven after time T, and finally, INVn+1 is driven after nT from driving INV1 In this case, a current driving ability of a rear stage inverter gradually increases at each delay time T. As a result, a voltage rise or fall of output Dout of driver 11 delays and a small slew rate is enabled. In this case, the slew rate of driver 11 becomes the minimum value.

Slew rates of n types can be enabled between the maximum and minimum values of the aforementioned slew rate can be enabled by selecting bits of slew rate control signal.

For data signal receiver 12, a NAND gate circuit, for example, can be used, but not limited to it. An arbitrary high-level output circuit can be connected to clock CLK of the NAND gate circuit by detecting rise or fall of the strobe signal or both of them and triggering the detection.

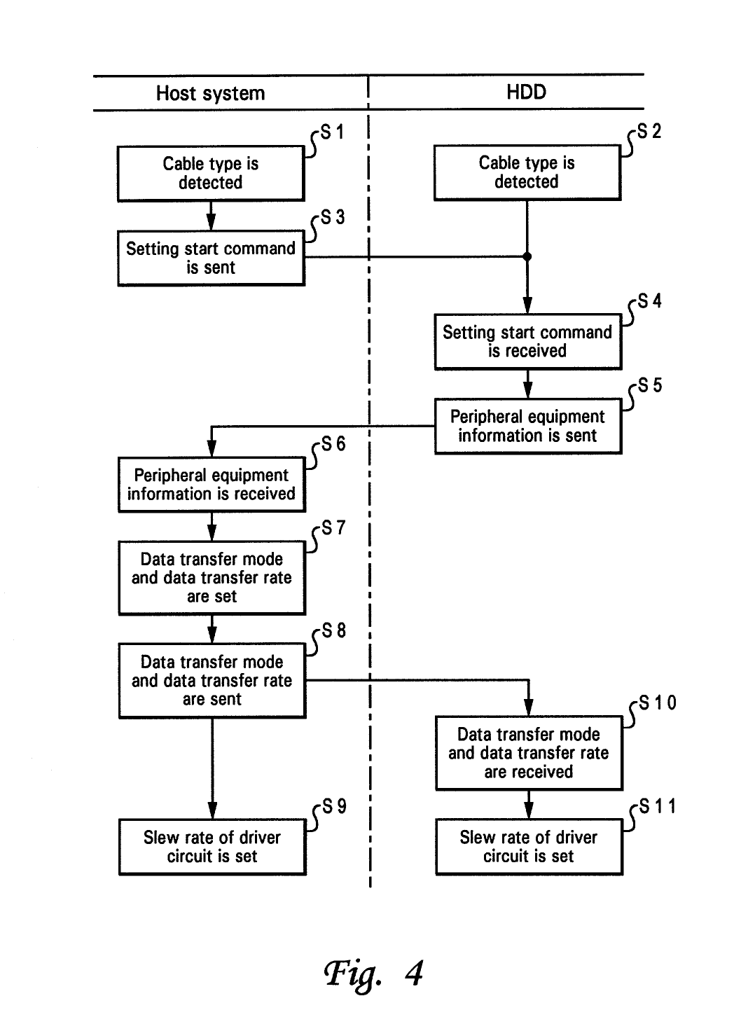

Next, a data transfer method using the DRU including driver 11 capable of aforementioned slew rate control is explained herein. FIG. 4 is a flowchart showing an example of the data transfer method in a preferred embodiment of the present invention. The following system is started by turning on the power of or resetting the computer system.

First, a cable type is detected at the host system side or HDD side, as depicted in blocks S1 and S2. The cable type (40 wire or 80 wire) will be used later to select the optimum value of a slew rate.

Next, host system 1 sends a setting start command of a data transfer mode to HDD 2 (HDD 2-1, HDD 2-2. or both), as illustrated in block S3. HDD 2 receives said command (block S4) and sends equipment information such as a data transfer mode and a data transfer rate supportable by HDD 2 to host system 1 (block S5).

Host system 1 receives the equipment information (block S6) and sets the data transfer mode and data transfer rate (block S7). The data transfer mode and data transfer rate are set so that they conform to the ATA/ATAPI specifications in consideration of the cable type. At setting, selecting the maximum transfer rate within the supportable range by the host system or HDD is desirable.

The set data transfer mode and data transfer rate are sent to HDD 2 (block S8) and HDD2 receives the information (block S10).

Host system 1 and HDD 2 respectively set the optimum slew rate as a signal transmission condition consisting of the set data transfer rate and cable type used (block S9 and S11). When setting a slew rate, the slew rate setting table is referred wherein the slew rates are recorded beforehand. For host system 1, the table can be stored in the main memory or AT controller ATC. For the HDD, the table can be stored in the memory or ATA interface circuit (ATAIFC).

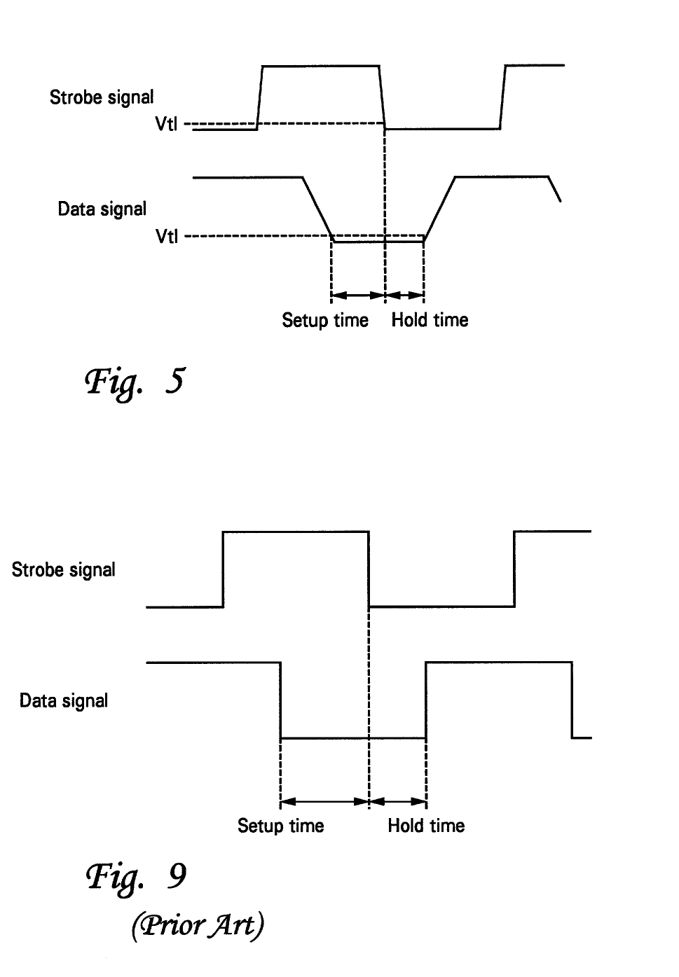

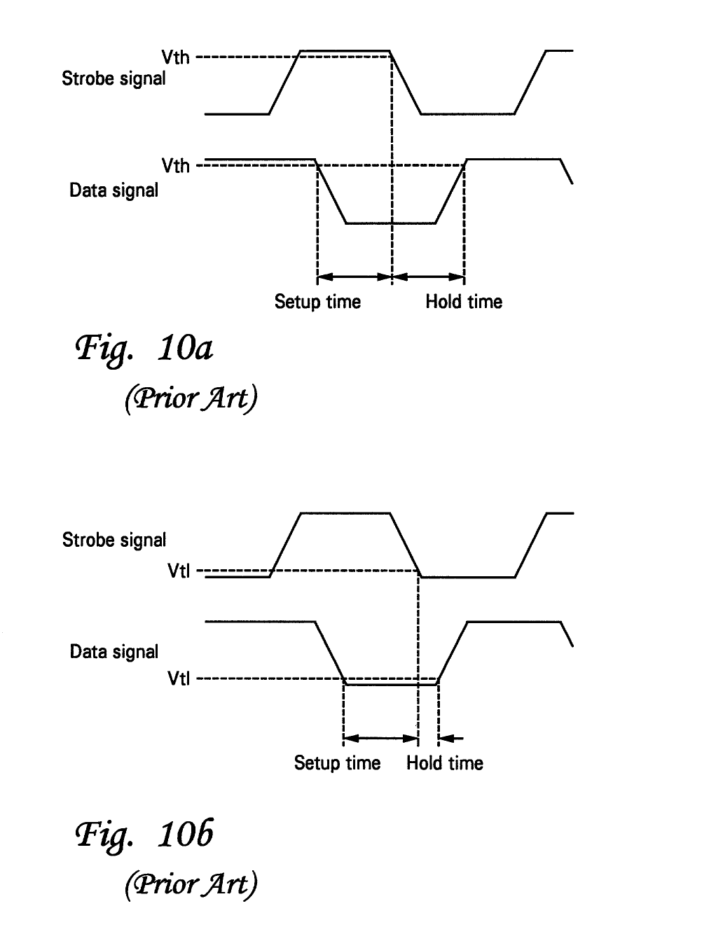

In the embodiment of the present invention, the optimum slew rate differs depending on whether it is a value set in driver 11 generating a data signal or in driver 11 generating a strobe signal. Accordingly, the slew rate of the strobe signal is set large and the slew rate of the data signal is set small. FIG. 5 shows an example of setting the slew rate of the strobe signal large and the slew rate of the data signal small. Thus, it can be known that the transition times of rise and fall times of the rectangle wave can be reduced by setting the slew rate of the strobe signal large and that the hold time can greatly be improved in the worst case (corresponding to FIG. 10(b)). On the other hand, because the slew rate of the data signal is small (transition times are long), a cross-talk noise can be inhibited. According to the embodiment of the present invention, the timing margins can be improved while inhibiting the cross-talk noise to the minimum level. In FIG. 5, an example of reading data when the strobe signal falls is illustrated, but even in the case of data reading at rise of the strobe signal, the effect of increasing the timing margins is the same. In this case the setup time deteriorates when the threshold value varies to the Vth side, but because the transition times of the strobe signal are shortened as in the mode of carrying out the invention, deterioration of the setup time is inhibited and the timing margins can be increased.

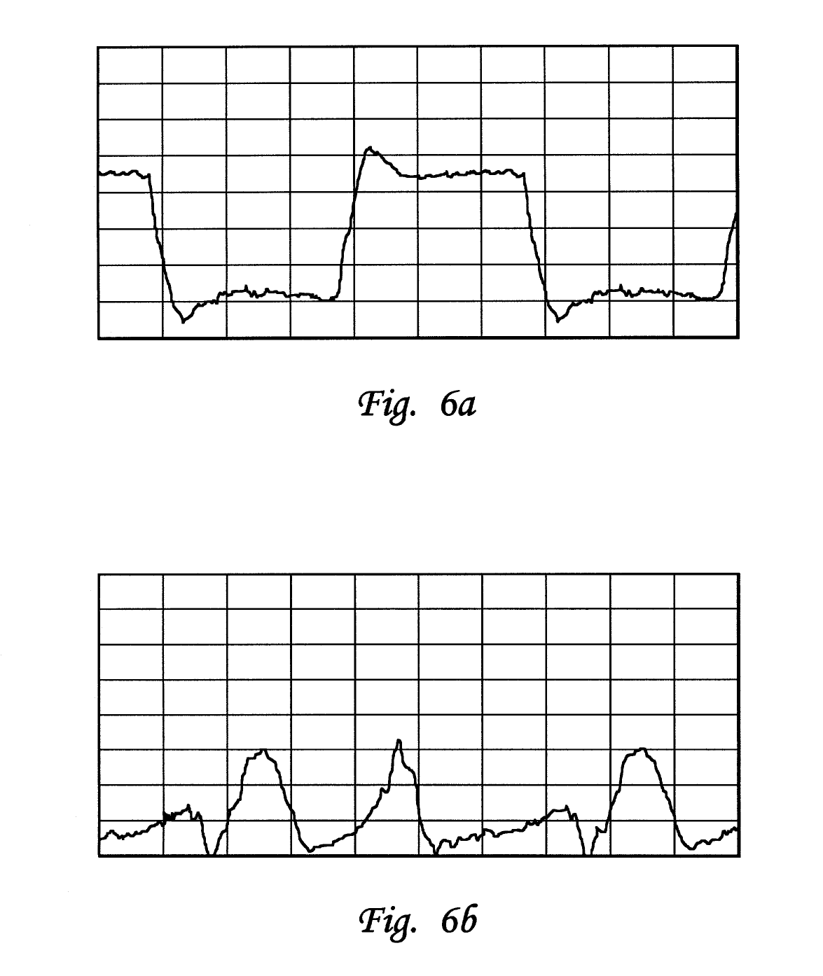

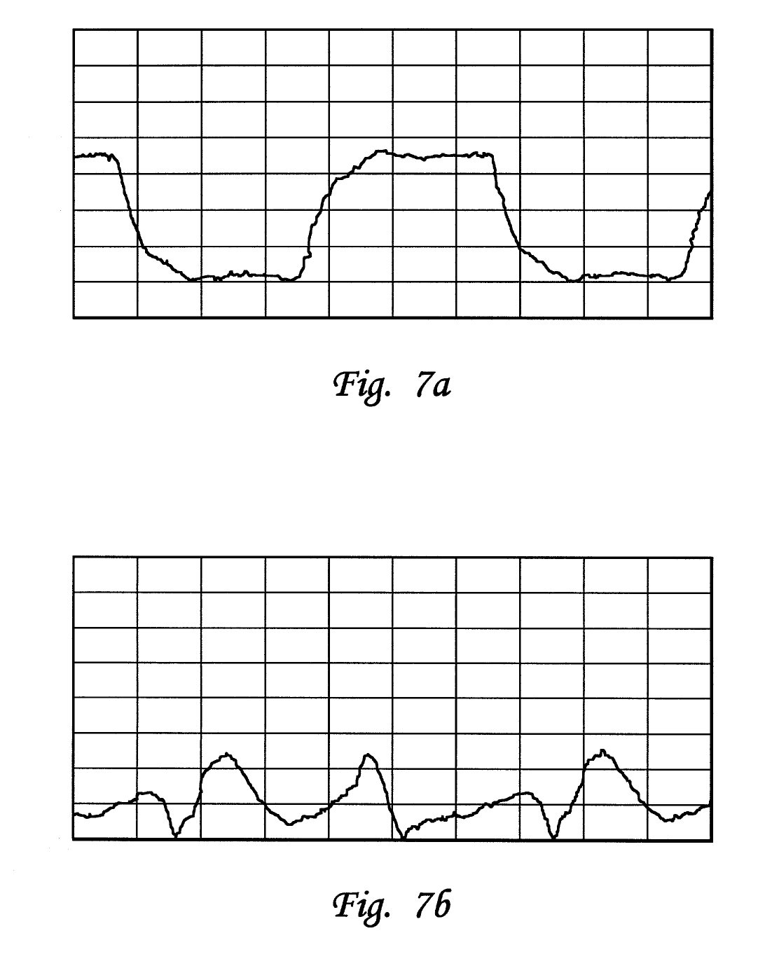

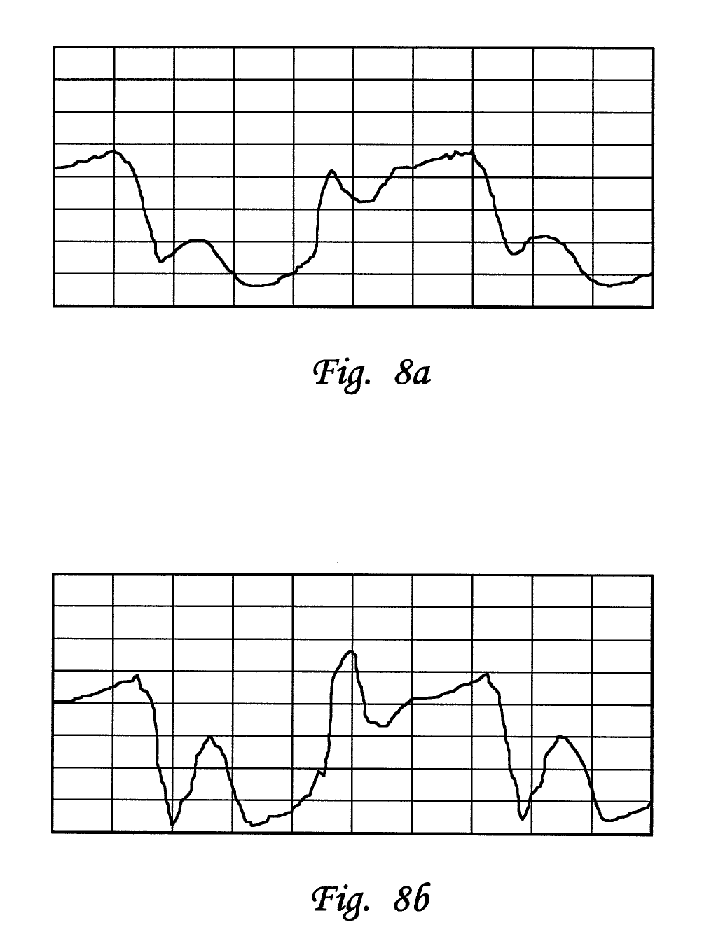

FIG. 6(a) shows a graph showing observation of the strobe signal of the receiver side by using the driver in the embodiment of the present invention. FIG. 6(b) shows a graph of the data signal whose low-level output from the receiver's view under the condition of full-swinging adjacent data signal lines. FIG. 7 shows a graph of the conventional strobe signal (a) and data signal (b) show for comparison. The slew rates of adjacent data signal lines in FIGS. 6 and 7(b) are set to small values. FIG. 8 shows a graph of the data signal at the receiver side when a slew rate is changed. FIG. 8(a) shows the case in which the slew rate is small. FIG. 8(b) shows the case in which the slew rate is large. The graph in FIG. 8 shows that a full-swing driver output indicating alternative repetition of low-level and high-level is given.

As FIG. 8 clearly shows, a noise level greatly differs when the slew rate of the data signal is changed. When the slew rate shown in FIG. 8(a) is small in comparison to the case in which the slew rate shown in FIG. 8(b) is large, the noise level is greatly inhibited. As shown by comparing FIGS. 6 and 7, the noise level of the data signal does not change greatly even though the slew rate of the strobe signal greatly changes. Accordingly, it can be known that the timing margins can be increased while inhibiting the influence of the noise by using the data transfer method of the mode of carrying out the invention.

Thus, the invention by the inventors is concretely explained according to the embodiment of the present invention, but the invention is not limited to said mode of carrying out the invention and can be changed in wide variety within the range of the objects.

For example, in said mode of carrying out the invention, the example of making the slew rate control signals at the rise and fall times of the rectangle wave is explained, but these slew rates can also be controlled differently. This control is enabled by making gate inputs of the pMOS transistor and nMOS transistor of rear stage inverters INV2 to INVn+1 independent.

In the above described embodiment of the present invention, the example of two HDDs installed is explained, but the number of installed HDD can also be one. In this case, if the number of HDDs is different, the load impedance from driver 11's view differs. Accordingly, in FIG. 4 of a preferred embodiment of the present invention, a step of inspecting the number of connected HDDs can be inserted as an arbitrary step before setting the data transfer rate and this number can be considered when determining the data transfer rate depicted in block S7. For example, optimum slew rates according to the numbers of connected HDDs can be recorded in the slew rate setting table and referred to.

In the above described embodiment of the present invention, HDD2 is indicated for example, but other peripheral equipment such as a CD-ROM, a DVD-ROM, and an MO can also be applied in the same manner.

In the described embodiment, examples of data and cables conforming to ATA/ATAPI are explained, but the invention is not limited thereto. For example, the invention is also applicable to other data transfer by or specifications of multiple data lines allocated in parallel to send a strobe signal together with a data signal such as an Small Computer System Interface (SCSI), film wiring, or wiring on a printed circuit board.

The slew rates need not be fixed to values in the slew rate setting table. For example, a slew rate value can dynamically be changed by measuring an error rate by using an error correction code (ECC). However, the condition of the invention that the slew rate of the strobe signal is greater than that of the data signal need be satisfied.

Effects obtained by representative inventions enclosed by the application are as follows: The timing margins can be increased and the reliability of data transfer can be improved without deteriorating the data transfer rate. The flexible adjustment engineering of a signal waveform enabling adjustment of data signal and strobe signal skews can be provided. The engineering of securing the reliability of data transfer regardless of the number of devices connected to the cables can be provided.

While the invention has been particularly shown and described with the reference to a preferred embodiment, it will be understood by those skilled in the art that various changes in form and detail may be made therein without departing from the spirit and scope of the invention

What is claimed is:

1. A data transfer system comprising:
a plurality of data lines for transferring data signals and at least one control line for transferring a control signal, said plurality of data lines and said at least one control line being allocated in parallel;
a data driver connected to at least one of said plurality of data lines;
a control driver connected to at least one of said at least one control line; and
a host system, coupled to send and receive said data signals and said control signal to and from at least one storage device, setting a data signal slew rate and a control signal slew rate such that said data signal slew rate is smaller than said control signal slew rate.

2. The data transfer system according to claim 1, further comprising a table containing an optimum value of said control signal slew rate, said optimum value dependent on a quantity of devices connected to said host system, wherein said host system sets said optimum value of said control signal slew rate in said control driver upon said host system determining said quantity of devices.

3. The data transfer system according to claim 1, wherein said host system sets a data signal rising slew rate independently of a data signal falling slew rate, and said host sets a control signal rising slew rate independently of a control signal falling slew rate.

4. The data transfer system according to claim 1, wherein said control signal is a clock signal.

5. The data transfer system according to claim 1, wherein said data signals and said control signal conform to AT Attachment (ATA) Specifications.

6. The data transfer system according to claim 1, wherein said data signals and said control signal conform to ATA Packet Interface (ATAPI) Specifications.

7. The data transfer system according to claim 1, wherein a transition time of said data signal between a first reference data voltage and a second reference data voltage is longer than a transition time of said control signal between a first reference control voltage and a second reference control voltage by at least 2 nanoseconds.

8. A data transfer method for transferring, between a host system and a storage device, data signals via a plurality of data lines and a control signal via at least one control line, said plurality of data lines and said at least one control line being allocated in parallel, said method comprising the steps of:
setting a data signal slew rate smaller than a control signal slew rate;
generating via a plurality of drivers the data signals having said data signal slew rate and the control signal having said control signal slew rate; and
receiving said data signals and said control signal.

9. The data transfer method according to claim 8 further comprising the steps of:
determining a quantity of devices connected to a host system; and
setting an optimum value of said data signal slew rate and an optimum value of said control signal slew rate by referring to a table correlating said quantity of said connected devices to said optimum values of said data signal slew rates and said control signal slew rates.

10. The data transfer method according to claim 8, wherein a data signal rising slew rate is set independently of a data signal falling slew rate, and a control signal rising slew rate is set independently of a control signal falling slew rate.

11. The data transfer method according to claim 8, wherein said control signal is a clock signal.

12. The data transfer method according to claim 8, wherein said data signals and said control signal conform to AT Attachment (ATA) Specifications.

13. The data transfer method according to claim 8, wherein said data signals and said control signal conform to ATA Packet Interface (ATAPI) Specifications.

14. The data transfer method according to claim 8, wherein a transition time of said data signal between a first reference data voltage and a second reference data voltage is longer than a transition time of said control signal between a first reference control voltage and a second reference control voltage by at least 2 nanoseconds.

15. A storage device connected to a host system, said storage device comprising at least one driver in an interface section of said storage device, said at least one driver capable of transmitting to the host system multiple data signals via multiple data signal lines and at least one control signal via at least one control signal line, said multiple data signal lines and said at least one control signal line being allocated in parallel, and said at least one driver capable of sending said data signals with a variable data signal slew rate and said at least one control signal with a variable control signal slew rate, said data signal slew rate having been set smaller than said control signal slew rate by the host system.

16. The storage device according to claim 15, wherein said storage device, being one of at least one storage devices connected to the host system, further comprises a table correlating a quantity of said at least one storage devices to optimum values of said data signal slew rate and said control signal slew rate, and wherein said at least one driver transmits said multiple data signals and said at least one control signal at said optimum values.

17. The storage device according to claim 15, wherein said host system sets a data signal rising slew rate independently of a data signal falling slew rate, and a control signal rising slew rate independently of a control signal falling slew rate.

18. The storage device according to claim 15, wherein said control signal is a strobe signal conforming to AT Attachment (ATA) Specifications.

19. The storage device according to claim 15, wherein said control signal is a strobe signal conforming to ATA Packet Interface (ATAPI) Specifications.

20. The storage device according to claim 15, wherein a transition time of said data signal between a first reference data voltage and a second reference data voltage is longer than a transition time of said control signal between a first reference control voltage and a second reference control voltage by at least 2 nanoseconds.

21. A computer system comprising:
a host system;
a storage device;
a cable for connecting said host system interface and said storage device interface, said cable comprising multiple data signal lines and at least one control signal line allocated in parallel;
at least one driver in said host system and at least one driver in said storage device, each said at least one driver in said host system and each said at least one driver in said storage device being capable of generating a data signal and a control signal, each said data signal having a variable data signal slew rate and each said control signal having a variable control signal slew rate;
wherein said host system sets said variable data signal slew rate smaller than said variable control signal slew rate.

22. The computer system according to claim 21, said computer system further comprising a table containing an optimum value of said control signal slew rate corresponding to a quantity of devices connected to said host system, wherein said host system sets said optimum value of said control signal slew rate at said control driver upon said host system determining said quantity of devices.

23. The computer system according to claim 21, wherein said host system sets a data signal rising slew rate independently of a data signal falling slew rate, and said host system sets a control signal rising slew rate independently of a control signal falling slew rate.

24. The computer system according to claims 21, wherein said control signal is a strobe signal conforming to AT Attachment (ATA) Specifications;

25. The computer system according to claim 21, wherein said control signal is a strobe signal conforming to ATA Packet Interface (ATAPI) Specifications.

26. The computer system according to claim 21, wherein a transition time of said data signal between a first reference data voltage and a second reference data voltage is longer than a transition time of said control signal between a first reference control voltage and a second reference control voltage by at least 2 nanoseconds.
